(19) United States
(12) Patent Application Publication
(10) Pub. No.: US 2024/0287358 A1
(43) Pub. Date: Aug. 29, 2024

(54) ADHESIVE SHEET, FLEXIBLE IMAGE DISPLAY MEMBER, AND FLEXIBLE IMAGE DISPLAY DEVICE

(71) Applicant: MITSUBISHI CHEMICAL CORPORATION, Tokyo (JP)

(72) Inventors: Sho YAMASHITA, Tokyo (JP); Daiki TABATA, Tokyo (JP)

(73) Assignee: MITSUBISHI CHEMICAL CORPORATION, Tokyo (JP)

(21) Appl. No.: 18/653,606

(22) Filed: May 2, 2024

Related U.S. Application Data
(63) Continuation of application No. PCT/JP2023/008712, filed on Mar. 8, 2023.

(30) Foreign Application Priority Data
Mar. 16, 2022 (JP) 2022-041294

(51) Int. Cl. C09J 133/10; C09J 4/00; C09J 7/30; C09J 11/02

(52) U.S. Cl. CPC C09J 133/10; C09J 4/00; C09J 7/30; C09J 11/02; C09J 2203/318; C09J 2301/30; C09J 2433/00

(57) ABSTRACT

The present disclosure provides an adhesive sheet formed from an adhesive composition containing a (meth)acrylic acid ester copolymer and a crosslinker, in which the (meth)acrylic acid ester copolymer contains, as components that constitute the copolymer, (A) a branched or linear C1 to C20 alkyl (meth)acrylic acid ester monomer, (B) a monomer having an alkylene glycol group in a molecule and having a (meth)acryloyl group, and (C) a nitrogen-containing vinyl monomer, and the adhesive sheet has a storage shear modulus at −30° C. (G′ (−30° C.)) of not greater than 250 kPa obtained by dynamic viscoelasticity measurement with a shearing mode at a frequency of 1 Hz, and has a strain recovery rate (400%, 1 minute) of not less than 70%.

### RELATED APPLICATIONS

This application is a continuation of International Application No. PCT/JP2023/008712, filed on Mar. 8, 2023, which claims priority to Japanese Patent Application No. 2022-041294, filed on Mar. 16, 2022, the entire contents of each of which are herein incorporated by reference.

### TECHNICAL FIELD

The present disclosure relates to an adhesive sheet that can be suitably used for an image display device composed of curves, a foldable and flexible image display device, and the like, and a flexible image display member and a flexible image display device using the adhesive sheet.

### BACKGROUND ART

In recent years, flexible image display devices that use organic light-emitting diodes (OLEDs) and quantum dots (QDs) have been developed and commercially used widely.

Flexible image display devices include bendable devices with image display surfaces having a curved shape, foldable devices capable of being repeatedly folded, rollable devices capable of being rolled, and stretchable devices capable of expanding and contracting.

Such image display devices have laminate structures in which a plurality of member sheets such as a cover lens, a circularly polarizing plate, a touch film sensor, and a light-emitting element are laminated with transparent adhesive sheets, and each of the laminate structures can be regarded as a laminated sheet in which the member sheet and the adhesive sheet are laminated.

Foldable and flexible display devices have various problems caused by interlayer stress when folded. For example, there has been a demand for laminated sheets that can quickly recover to a flat state when a screen is opened from a folded state, without leaving the effect caused by being placed into a bent state.

Furthermore, repeated folding operations apply stress to member sheets, which are adherends of adhesive sheets, to possibly cause cracking, finally leading to breakage. Laminated sheets are also required to be durable against repeated folding operations particularly at low temperatures which are severe conditions.

As for such an adhesive sheet for a foldable and bendable display device, for example, PTL 1 discloses an adhesive composition for a foldable display, in which the adhesive composition containing an acrylic polymer and a crosslinker has a storage modulus after curing that satisfies 60×10⁴ to 95×10⁴ Pa, 8×10⁴ to 11×10⁴ Pa, and 2×10⁴ to 5×10⁴ Pa at temperatures of −20° C., 25° C., and 200° C., respectively.

PTL 2 discloses an adhesive composition for a foldable display including a (meth)acrylic copolymer containing a constitutional unit derived from a monomer having a hydroxyl group and a constitutional unit derived from an alkyl (meth)acrylic acid ester monomer, and a crosslinker, in which when the adhesive composition is formed into an adhesive layer, the storage modulus at −20° C. is not less than 0.05 MPa and not greater than 0.5 MPa, the ratio of the storage modulus at −20° C. to the storage modulus at 100° C. is not greater than 15.0, and the gel fraction is not less than 50% by mass.

### RELATED ART DOCUMENT

### Patent Document

PTL 1: JP-B-6845952
PTL 2: JP-A-2021-91772

### SUMMARY

### Problems to be Solved by the Disclosure

The adhesive sheet for a foldable and bendable display device composed of an acrylic polymer and a crosslinker described in PTL 1 has a high adhesive force and recovery rate. Therefore, delamination at the time of folding is alleviated and the adhesive sheet can quickly recover to a flat state when opened from a folded state. However, due to a high storage modulus at low temperature, a member sheet, which is an adherend of the adhesive sheet, may be subject to stress by repeated folding operations and be easily broken.

The adhesive sheet for a foldable and bendable display device composed of a (meth)acrylic polymer and a crosslinker described in PTL 2 has a low storage modulus at low temperature. Therefore, stress on a member sheet by repeated folding operations is reduced. However, PTL 2 does not mention recoverability.

The present disclosure therefore provides an adhesive sheet that can reduce interlayer stress when folded, particularly when folded in a low temperature state, has excellent durability that suppresses cracking of a member sheet or a flexible member (also referred to as “low-temperature bending durability”), and has excellent recoverability that allows quick recovery to a flat state when a folding operation is performed (also referred to as “strain recoverability”), and also provides a flexible image display device member and a flexible image display device using the adhesive sheet.

### Means for Solving the Problems

An adhesive sheet according to the present disclosure has the following constitution in order to solve the above problems.

[1] An adhesive sheet formed from an adhesive composition comprising a (meth)acrylic acid ester copolymer and a crosslinker, wherein
the (meth)acrylic acid ester copolymer includes, as components that constitute the copolymer, (A) a branched or linear C1 to C20 alkyl (meth)acrylic acid ester monomer, (B) a monomer having an alkylene glycol group in a molecule and having a (meth)acryloyl group, and (C) a nitrogen-containing vinyl monomer, and
the adhesive sheet has a storage shear modulus at −30° C. (G′ (−30° C.)) of not greater than 250 kPa obtained by dynamic viscoelasticity measurement with a shearing mode at a frequency of 1 Hz, and has a strain recovery rate (400%, 1 minute) of not less than 70%.

[2] The adhesive sheet according to [1], wherein the monomer component (A) is a linear C8 to C12 alkyl (meth)acrylic acid ester monomer.

[3] The adhesive sheet according to [1] or [2], wherein the (meth)acrylic acid ester copolymer further comprises (D) a hydroxyl group-containing monomer and/or a carboxy group-containing monomer.

[4] The adhesive sheet according to any one of [1] to [3], wherein the adhesive composition comprises 20 to 90 parts by mass of the crosslinker with respect to 100 parts by mass of the (meth)acrylic acid ester copolymer.

[5] The adhesive sheet according to any one of [1] to [4], wherein the adhesive composition comprises 30 to 90 parts by mass of the crosslinker with respect to 100 parts by mass of the (meth)acrylic acid ester copolymer.

[6] The adhesive sheet according to any one of [1] to [5], wherein the crosslinker comprises a (meth)acrylate having an average functionality of not less than 1.0 and less than 2.0.

[7] The adhesive sheet according to any one of [1] to [6], wherein the crosslinker comprises a monofunctional urethane (meth)acrylate.

[8] The adhesive sheet according to any one of [1] to [7], wherein the monomer component (B) is alkoxypolyalkylene glycol (meth)acrylate.

[9] The adhesive sheet according to [8], wherein the alkoxypolyalkylene glycol (meth)acrylate is contained in an amount of 2 to 4% by mass in an entirety of monomer components that constitute the (meth)acrylic acid ester copolymer.

[10] The adhesive sheet according to any one of [1] to [9], wherein the adhesive composition comprises a photopolymerization initiator.

[11] A flexible image display device member comprising a constitution in which two flexible members are laminated with the adhesive sheet according to any one of [1] to [10] interposed.

[12] A flexible image display device comprising the flexible image display device member according to [11].

### Effects of the Disclosure

The adhesive sheet according to the present disclosure has a low storage modulus at low temperature such as −30° C., has excellent strain recoverability, and can be suitably used in particular for flexible image display devices.

### EMBODIMENTS OF THE DISCLOSURE

Hereinafter, the present disclosure will be described in detail. However, the present disclosure is not limited to embodiments described below.

### <Meaning of Terms>

In the present disclosure, “sheet” conceptually encompasses sheet, film, and tape.

As used herein “(meth)acryl” has a meaning that encompasses “acryl” and “methacryl”, and “(meth)acrylate” has a meaning that encompasses “acrylate” and “methacrylate”.

The expression “panel” as used in “image display panel” and “protection panel” is intended to encompass plate, sheet, and film.

As used herein “X to Y” (where X and Y are given numbers) is intended to encompass a meaning of “preferably greater than X” and “preferably less than Y” unless otherwise specified, in addition to a meaning of “not less than X and not greater than Y”.

The expression “not less than X” (where X is a given number) is intended to encompass a meaning of “preferably greater than X” unless otherwise specified. The expression “not greater than Y” (where Y is a given number) is intended to encompass a meaning of “preferably smaller than Y” unless otherwise specified.

Further, the expression “X and/or Y” (where X and Y are each a given form) is intended to mean at least one of X and Y and include the following three meanings: only X; only Y; and X and Y.

### <<Adhesive Sheet>>

The adhesive sheet according to an example of the embodiment of the present disclosure (hereinafter also referred to as “present adhesive sheet”) is formed from an adhesive composition containing a (meth)acrylic acid ester copolymer and a crosslinker (hereinafter also referred to as “present adhesive composition”).

### <(Meth)Acrylic Acid Ester Copolymer>

In order to adjust viscoelasticity and a recovery rate to a predetermined range, it is preferable that the (meth)acrylic acid ester copolymer contains, as monomer components that constitute the copolymer, (A) a branched or linear C1 to C20 alkyl (meth)acrylic acid ester monomer, (B) a monomer having an alkylene glycol group in a molecule and having a (meth)acryloyl group, and (C) a nitrogen-containing vinyl monomer.

### <Monomer Component (A)>

The branched or linear C1 to C20 alkyl (meth)acrylic acid ester monomer (A) is a branched or linear alkyl (meth)acrylic acid ester monomer with a C1 to C20 alkyl group. Examples include linear alkyl (meth)acrylic acid esters such as methyl (meth)acrylate, ethyl (meth)acrylate, propyl (meth)acrylate, butyl (meth)acrylate (n-butyl (meth)acrylate), pentyl (meth)acrylate, hexyl (meth)acrylate, heptyl (meth)acrylate, octyl (meth)acrylate, nonyl (meth)acrylate, decyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl (meth)acrylate.

Other examples include branched alkyl (meth)acrylic acid esters such as isopropyl (meth)acrylate, isobutyl (meth)acrylate, s-butyl (meth)acrylate, t-butyl (meth)acrylate, isopentyl (meth)acrylate, 2-ethylhexyl (meth)acrylate, isooctyl (meth)acrylate, isononyl (meth)acrylate, isodecyl (meth)acrylate, isomistylyl (meth)acrylate, isostearyl (meth)acrylate, 2-propylheptyl (meth)acrylate, isoundecyl (meth)acrylate, isododecyl (meth)acrylate, isotridecyl (meth)acrylate, isopentadecyl (meth)acrylate, isohexadecyl (meth)acrylate, and isoheptadecyl (meth)acrylate.

These can be used alone or in combination of two or more.

As the branched or linear C1 to C20 alkyl (meth)acrylic acid ester monomer (A), linear C8 to C12 alkyl (meth)acrylic acid ester monomers are particularly preferred in order to adjust viscoelasticity and a recovery rate to a predetermined range. Among these, it is preferable that any one or more alkyl (meth)acrylic acid esters selected from octyl (meth)acrylate (n-octyl (meth)acrylate) and 2-ethylhexyl (meth)acrylate are the main component of the entirety of monomer components that constitute the (meth)acrylic acid ester copolymer.

As used herein “main component” means a component that accounts for the highest mass proportion in the entirety of monomer components that constitute the (meth)acrylic acid ester copolymer. Specifically, the main component is a monomer component that accounts for not less than 50% by mass in the entirety of monomer components, in particular, a monomer component that accounts for not less than 55% by mass and even more preferably not less than 60% by mass.

### <Monomer Component (B)>

Examples of the monomer (B) having an alkylene glycol group in a molecule and having a (meth)acryloyl group include branched or linear C1 to C20 alkylene glycol, dialkylene glycol, trialkylene glycol, and polyalkylene glycol (meth)acrylates.

In terms of improving adhesive force, the carbon number of the alkylene group is preferably 1 to 4 and particularly preferably 2 to 3.

The number (n) of repeating units of the alkylene group is preferably 5 to 15, even more preferably 7 to 13, and particularly preferably 9 to 11 in terms of recoverability.

In terms of recoverability, a linear alkylene group is preferred.

Furthermore, acrylates are particularly preferred in view of suppressing increase in storage shear modulus (G′) at low temperature to improve bendability.

Other examples include alkoxyalkylene glycol (meth)acrylates, alkoxydialkylene glycol (meth)acrylates, alkoxytrialkylene glycol (meth)acrylates, and alkoxypolyalkylene glycol (meth)acrylates, in which a functional group including a C1 to C18 alkyl group and a C1 to C4 alkylene glycol group is introduced, and phenoxyalkylene glycol (meth)acrylates, phenoxydialkylene glycol (meth)acrylates, phenoxytrialkylene glycol (meth)acrylates, and phenoxypolyalkylene glycol (meth)acrylates, in which a functional group including a phenoxy group and a C1 to C4 alkylene glycol group is introduced.

These can be used alone or in combination of two or more.

Among these, alkoxypolyalkylene glycol (meth)acrylates such as methoxypolyethylene glycol (meth)acrylate, methoxypolypropylene glycol (meth)acrylate, and methoxypolyneopentyl glycol (meth)acrylate are preferred. Among these, in terms of low glass transition temperature (Tg) and availability, one or two or more selected from the group consisting of alkoxypolyethylene glycol (meth)acrylate and alkoxypolypropylene glycol (meth)acrylate are preferred. In particular, one or two or more selected from the group consisting of methoxypolyethylene glycol (meth)acrylate, ethoxypolyethylene glycol (meth)acrylate, methoxypolypropylene glycol (meth)acrylate, and ethoxypolypropylene glycol (meth)acrylate are preferred.

### <Monomer Component (C)>

Examples of the nitrogen-containing vinyl monomer (C) include (meth)acrylamide, N-tert-butylacrylamide, N-vinylpyrrolidone, N, N-dimethylacrylamide, N,N-ethylacrylamide, N,N-dimethylaminopropylacrylamide, N-methylol(meth)acrylamide, N-methylolpropane(meth)acrylamide, N-methoxymethyl(meth)acrylamide, N-butoxymethyl(meth)acrylamide, diacetone(meth)acrylamide, maleic acid amide, maleimide, N-isopropylacrylamide, N-phenylacrylamide, dimethylaminopropylacrylamide, N-vinylcaprolactam, acryloylmorpholine, dimethylaminoethyl acrylate, and acryloylpiperidine.

Other examples include aminoalkyl (meth)acrylates such as aminomethyl (meth)acrylate, aminoethyl (meth)acrylate, aminopropyl (meth)acrylate, and aminoisopropyl (meth)acrylate, and amino group-containing (meth)acrylate monomers such as N-alkylaminoalkyl (meth)acrylate, N, N-dimethylaminoethyl (meth)acrylate, and N, N-dimethylaminopropyl (meth)acrylate.

These can be used alone or in combination of two or more.

### (Other Monomers)

Examples of other monomer components copolymerizable with (A) to (C) include hydroxyl group-containing monomers (except for alkylene glycol (meth)acrylates as (B)), carboxy group-containing monomers, epoxy group-containing monomers, and other copolymerizable monomers.

Among those above, it is particularly preferable to use (D) a hydroxyl group-containing (meth)acrylate monomer and/or a carboxy group-containing (meth)acrylate monomer in terms of improving adhesive force of the adhesive sheet to an adherend.

These can be used alone or in combination of two or more.

### (Hydroxyl Group-Containing Monomer)

Examples of the hydroxyl group-containing monomer include 2-hydroxyethyl (meth)acrylate, 2-hydroxypropyl (meth)acrylate, 2-hydroxy-1-methylethyl (meth)acrylate, 3-hydroxypropyl (meth)acrylate, 2-hydroxybutyl (meth)acrylate, 4-hydroxybutyl (meth)acrylate, glycerol mono(meth)acrylate, polyethylene glycol mono(meth)acrylate, polypropylene glycol mono(meth)acrylate, polyethylene glycol polypropylene glycol mono(meth)acrylate, polyethylene glycol polybutylene glycol mono(meth)acrylate, polypropylene glycol polybutylene glycol mono(meth)acrylate, and hydroxyphenyl (meth)acrylate.

Among these, it is particularly preferable to use one or more hydroxyl group-containing (meth)acrylates selected from the group consisting of 2-hydroxyethyl (meth)acrylate and 4-hydroxybutyl (meth)acrylate, in view of improving adhesive force of the adhesive sheet to an adherend.

These can be used alone or in combination of two or more.

### (Carboxy Group-Containing Monomer)

Examples of the carboxy group-containing monomer include (meth)acrylic acid, 2-(meth)acryloyloxyethylhexahydrophthalic acid, 2-(meth)acryloyloxypropylhexahydrophthalic acid, 2-(meth)acryloyloxyethylphthalic acid, 2-(meth)acryloyloxypropylphthalic acid, 2-(meth)acryloyloxyethylmaleic acid, 2-(meth)acryloyloxypropylmaleic acid, 2-(meth)acryloyloxyethylsuccinic acid, 2-(meth)acryloyloxypropylsuccinic acid, crotonic acid, fumaric acid, maleic acid, itaconic acid, citraconic acid, monomethyl maleate, monoethyl maleate, monooctyl maleate, monomethyl itaconate, monoethyl itaconate, monobutyl itaconate, monooctyl itaconate, monomethyl fumarate, monoethyl fumarate, monobutyl fumarate, monooctyl fumarate, and monoethyl citraconate. Among these, except for (meth)acrylic acid, in particular, 2-(meth)acryloyloxyethylsuccinic acid and 2-(meth)acryloyloxypropylsuccinic acid are particularly preferred in view of improving adhesive force of the adhesive sheet to an adherend.

These can be used alone or in combination of two or more.

Examples of the epoxy group-containing monomer include glycidyl (meth)acrylate, methylglycidyl (meth)acrylate, 3,4-epoxycyclohexylmethyl (meth)acrylate, and 4-hydroxybutyl (meth)acrylate glycidyl ether.

These can be used alone or in combination of two or more.

Examples of the other copolymerizable monomers include acid anhydride group-containing monomers such as maleic anhydride and itaconic anhydride, heterocyclic basic monomers such as vinylpyridine and vinylcarbazole, and macromonomers.

These can be used alone or in combination of two or more.

A polyfunctional (meth)acrylate may be used in combination as a monomer component that constitutes the (meth)acrylic acid ester copolymer. As the polyfunctional (meth)acrylate, a bifunctional (meth)acrylate is preferred, and in particular, a bifunctional urethane (meth)acrylate is preferred in terms of facilitating adjustment of the loss shear modulus (G″ (23° C.)) of the adhesive sheet and in terms of facilitating formation of an appropriate crosslinked network to achieve good recoverability.

Examples of the bifunctional (meth)acrylate include 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, neopentyl glycol hydroxypivalate di(meth)acrylate, dicyclopentanyl di(meth)acrylate, caprolactone-modified dicyclopentenyl di(meth)acrylate, ethylene oxide-modified phosphoric acid di(meth)acrylate, di(acryloxyethyl)isocyanurate, and allylated cyclohexyl di(meth)acrylate.

The bifunctional urethane (meth)acrylate is a urethane (meth)acrylate having two (meth)acryloyloxy groups (CHR═C(═O)O—, where R is a hydrogen atom or a methyl group) and a urethane group (—NHC(═O)O—). A bifunctional urethane acrylate usually has a polyurethane chain which is a polycondensation reaction product of diol and diisocyanate, and (meth)acryloyl groups bonded to both ends of the polyurethane chain.

Examples of the diol that can be used as a raw material of the bifunctional urethane (meth)acrylate include polycarbonatediol, polyesterdiol, polyetherdiol, and polycaprolactonediol.

These can be used alone or in combination of two or more.

Examples of the diisocyanate that can be used as a raw material of the bifunctional urethane acrylate include tolylene diisocyanate, xylylene diisocyanate, diphenylmethane diisocyanate, hexamethylene diisocyanate, trimethylhexamethylene diisocyanate, tetramethylxylylene diisocyanate, isophorone diisocyanate, hydrogenated tolylene diisocyanate, hydrogenated xylylene diisocyanate, hydrogenated diphenylmethane diisocyanate, m-phenylene diisocyanate, biphenylene diisocyanate, tetramethylene diisocyanate, and hexamethylene diisocyanate.

These can be used alone or in combination of two or more.

Examples of a monofunctional acrylic monomer having a hydroxyl group that can be used as a raw material of the bifunctional urethane acrylate include 2-hydroxyethyl (meth)acrylate, 4-hydroxybutyl (meth)acrylate, 2-hydroxypropyl (meth)acrylate, 2-hydroxybutyl (meth)acrylate, 6-hydroxyhexyl (meth)acrylate, and 1,4-cyclohexanedimethanol mono(meth)acrylate.

These can be used alone or in combination of two or more.

In the entirety of monomer components that constitute the (meth)acrylic acid ester copolymer, the content of the branched or linear C1 to C20 alkyl (meth)acrylic acid ester monomer (A) is preferably 60 to 90% by mass, more preferably 65 to 85% by mass, and most preferably 70 to 80% by mass, in view of adjusting viscoelasticity to a predetermined range.

Further, in the entirety of monomer components that constitute the (meth)acrylic acid ester copolymer, the content of the monomer (B) having an alkylene glycol group in a molecule and having a (meth)acryloyl group is preferably 1 to 5% by mass, more preferably 1.5 to 4.5% by mass, and most preferably 2 to 4% by mass in view of suppressing increase in storage shear modulus (G′) at low temperature to improve bendability.

In particular, in the entirety of monomer components that constitute the (meth)acrylic acid ester copolymer, the content of the alkoxypolyalkylene glycol (meth)acrylate is preferably 2 to 4% by mass.

Further, in the entirety of monomer components that constitute the (meth)acrylic acid ester copolymer, the content of the nitrogen-containing vinyl monomer (C) is preferably 0.1 to 5% by mass, more preferably 0.5 to 4% by mass, and most preferably 1 to 3% by mass in view of improving strain recoverability.

Further, the content of the other monomers is preferably 8 to 30% by mass, more preferably 10 to 25% by mass, and most preferably 12 to 20% by mass in view of improving adhesive force of the adhesive sheet to an adherend.

The content of the polyfunctional (meth)acrylate is preferably 0 to 2% by mass, more preferably 0.25 to 1.5% by mass, and most preferably 0.5 to 1% by mass in view of facilitating adjustment of the loss shear modulus (G″ (23° C.)) of the adhesive sheet and in view of facilitating formation of an appropriate crosslinked network to achieve good recoverability.

### <Crosslinker>

The present adhesive composition contains a crosslinker in addition to the (meth)acrylic acid ester copolymer in order to reduce the storage modulus at low temperature and adjust to desired viscoelasticity.

Examples of the crosslinker used in the present adhesive composition include (meth)acrylate crosslinkers, isocyanate crosslinkers, epoxy crosslinkers, oxazoline crosslinkers, aziridine crosslinkers, melamine crosslinkers, carbodiimide crosslinkers, hydrazine crosslinkers, amine crosslinkers, peroxide crosslinkers, metal chelate crosslinkers, metal alkoxide crosslinkers, and metal salt crosslinkers.

These can be used alone or in combination of two or more.

In the present adhesive composition, it is preferable to use a photo-crosslinker which is a compound having a property of being cured by light radiation, among crosslinkers, in terms of agingless and the ease of adjusting the degree of crosslinking. This can form a crosslinked structure with the (meth)acrylic acid ester copolymer.

As used herein “forming a crosslinked structure” includes not only a case where polymer chains are crosslinked through a chemical bond but also a case where a (pseudo) crosslink is formed by a non-covalent bond by an interaction such as hydrogen bond in a polymer chain or between polymer chains, electrostatic interaction, or van der Waals force.

The crosslinked structure also includes a case where crosslinkers are crosslinked through a chemical bond and a case where polymer chains or a polymer chain and a crosslinker are intertwined to form a pseudo crosslink.

The photo-crosslinker is preferably a compound having an ethylenically unsaturated group in a molecule in view of easily forming a crosslinked structure with the (meth)acrylic acid ester copolymer. In particular, a (meth)acrylate is preferred, and a (meth)acrylate having a glass transition temperature of not greater than −30° C., more preferably not greater than −35° C. when formed into a homopolymer, that is, when polymerized alone into a polymer, is more preferred. The lower limit of the glas0s transition temperature is usually −80° C.

When the photo-crosslinker has a glass transition temperature in such a range, the (meth)acrylic acid ester copolymer can be set to a relatively low glass transition temperature.

Accordingly, the present adhesive sheet can achieve particularly excellent effects of imparting flexibility that withstands buckling at the time of bending deformation, and also providing bending durability, while ensuring adhesiveness.

Examples of the (meth)acrylates include polyfunctional (meth)acrylates. In addition, monofunctional (meth)acrylates are also preferred, and monofunctional urethane (meth)acrylates are even more preferred.

The polyfunctional (meth)acrylate may be a mixture including a small amount of monofunctional (meth)acrylate as a by-product, and the monofunctional (meth)acrylate may be a mixture including a small amount of polyfunctional (meth)acrylate.

Further, the crosslinker is preferably a (meth)acrylate having an average functionality of not less than 1.0 and less than 2.0. If the average functionality is not less than the lower limit above, an appropriate crosslinked structure can be formed to retain a sheet shape. If the average functionality is less than the upper limit above, the crosslinking density does not become too high, and the storage modulus can be controlled to be low, resulting in an adhesive sheet having excellent adhesiveness to a variety of member sheets and excellent flexibility. In this respect, the average functionality of the crosslinker is preferably 1.05 to 1.8 and more preferably 1.1 to 1.6.

As used herein the average functionality means the average number of (meth)acryloyl groups present in a molecule of the crosslinker.

As used in the subject application “monofunctional” means having an average functionality of not less than 1.0 and not greater than 1.2.

Examples of the method of adjusting the average functionality of the crosslinker to the above range include a method of using a (meth)acrylate oligomer with an average addition number of (meth)acryloyl group of not less than 1.0 and less than 2.0 as a crosslinker, and a method of using a mixture of polyfunctional (meth)acrylate and monofunctional (meth)acrylate as a crosslinker.

Further, it is preferable that the crosslinker is a (meth)acrylate having an alkylene glycol skeleton. The crosslinker having the above structure is preferable in that the affinity for the monomer component (B) in the (meth)acrylic acid ester copolymer is increased, and consequently, the compatibility of the adhesive composition is improved and the control of storage modulus at low temperature becomes easy, facilitating production of an adhesive sheet with excellent low-temperature bending durability.

Examples of the glycol skeleton include polyethylene glycol skeleton, polypropylene glycol skeleton, polytetramethylene glycol skeleton, and polyhexamethylene glycol skeleton. Among these, polyethylene glycol skeleton and/or polypropylene glycol skeleton are particularly preferred.

Examples of the polyfunctional (meth)acrylate include ester compounds of (meth)acrylic acid and polyhydric alcohol, such as (poly)ethylene glycol di(meth)acrylate, (poly)propylene glycol di(meth)acrylate, neopentyl glycol di(meth)acrylate, pentaerythritol di(meth)acrylate, pentaerythritol tri(meth)acrylate, dipentaerythritol penta(meth)acrylate, dipentaerythritol hexa(meth)acrylate, 1,2-ethylene glycol di(meth)acrylate, 1,6-hexanediol di(meth)acrylate, 1,12-dodecanediol di(meth)acrylate, trimethylolpropane tri(meth)acrylate, and tetramethylolmethane tri(meth)acrylate; allyl (meth)acrylate; vinyl (meth)acrylate; divinylbenzene; epoxy acrylate; polyester acrylate; urethane acrylate; butyl di(meth)acrylate; hexyl di(meth)acrylate, and the like.

The monofunctional urethane (meth)acrylate can be obtained by reacting polyhydric alcohol, polyisocyanate, and (meth)acrylate having a hydroxy group.

Examples of the polyhydric alcohol include poly C2-C6 alkenylene glycol such as polybutadiene glycol, hydrogenated polybutadiene glycol, polyisoprene glycol, and hydrogenated polyisoprene glycol, and hydrogenated poly C2-C6 alkenylene glycol; and C1 to C10 alkylene glycols such as neopentyl glycol, 3-methyl-1,5-pentanediol, ethylene glycol, propylene glycol, 1,4-butanediol, and 1,6-hexanediol, or poly C2-C10 alkylene glycol in which one or more selected from these alkylene glycols are condensed through an ether bond.

Examples of the polyisocyanate include isophorone diisocyanate, hexamethylene diisocyanate, tolylene diisocyanate, xylene diisocyanate, diphenylmethane-4,4′-diisocyanate, and dicyclopentanyl diisocyanate.

Examples of the (meth)acrylate having a hydroxy group include hydroxyethyl (meth)acrylate, hydroxypropyl (meth)acrylate, hydroxybutyl (meth)acrylate, dimethylolcyclohexyl mono(meth)acrylate, and hydroxycaprolactone (meth)acrylate.

Among monofunctional urethane (meth)acrylates, a monofunctional urethane acrylate having a polypropylene glycol skeleton is preferred in view of low glass transition temperature and improving strain recoverability, and in particular, a monofunctional urethane acrylate represented by the following formula 1 is particularly preferred.

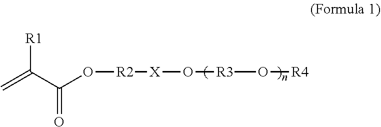

(In formula 1, R1 is hydrogen or a methyl group, X is a urethane bond, R2, R3, and R4 each represent an alkyl group, and n is an integer of not less than 2.)

The weight average molecular weight (Mw) of the crosslinker is preferably 1000 to 100000, more preferably 3000 to 50000, and even more preferably 5000 to 30000, in view of obtaining an adhesive composition with high cohesiveness.

In the present adhesive sheet, the weight average molecular weight (Mw) can be determined, for example, as follows.

### (Method for Measuring Weight Average Molecular Weight)

A measurement sample is prepared by dissolving 4 mg of the crosslinker in 12 mL of tetrahydrofuran (THF), and a molecular weight distribution curve is measured under the following conditions by using a gel permeation chromatography (GPC) analyzer (HLC-8320 GPC available from Tosoh Corporation) to determine the weight average molecular weight (Mw).
Guard column: TSK guard column HXL
Separation column: TSK gel GMHXL (4 columns)
Temperature: 40° C.
Injection amount: 100 μL
In terms of polystyrene standard
Solvent: THF
Flow rate: 1.0 mL/minute

The content of the crosslinker is preferably in a range of 1 to 100 parts by mass, more preferably in a range of 10 to 95 parts by mass, even more preferably in a range of 15 to 95 parts by mass, particularly preferably in a range of 30 to 90 parts by mass, and most preferably in a range of 50 to 90 parts by mass with respect to 100 parts by mass of the (meth)acrylic acid ester copolymer. Among these, not less than 55 parts by mass and not greater than 80 parts by mass, and particularly not less than 60 parts by mass and not greater than 75 parts by mass is preferred. Containing the crosslinker in such a proportion achieves both adhesive force and bending durability in a balanced manner.

In addition to the above preferable ranges of content of the crosslinker, the content of the crosslinker is preferably in a range of 20 to 90 parts by mass, more preferably in a range of 22 to 88 parts by mass, and even more preferably in a range of 25 to 85 parts by mass with respect 100 parts by mass of the (meth)acrylic acid ester copolymer, in view of obtaining an adhesive sheet with excellent strain recoverability.

### <Photopolymerization Initiator>

It is preferable that the present adhesive composition further contains a photopolymerization initiator.

Preferred examples of the photopolymerization initiator include compounds that generate active radicals by radiation of light such as ultraviolet ray and visible ray, more specifically, light with a wavelength of 200 to 780 nm.

The photopolymerization initiator may be either a cleavage type or a hydrogen abstraction type.

It is preferable to use a hydrogen abstraction-type photopolymerization initiator, because if so, the (meth)acrylic acid ester copolymer also undergoes a hydrogen abstraction reaction and not only the crosslinker but also the (meth)acrylic acid ester copolymer is incorporated into the crosslinked structure, thereby forming a crosslinked structure with many crosslinking points.

Examples of the hydrogen abstraction-type photopolymerization initiator include benzophenone, 4-methylbenzophenone, 2,4,6-trimethylbenzophenone, 4-phenylbenzophenone, 3,3′-dimethyl-4-methoxybenzophenone, 4-(meth)acryloyloxybenzophenone, methyl 2-benzoylbenzoate, methyl benzoylformate, bis(2-phenyl-2-oxoacetate)oxybisethylene, 4-(1,3-acryloyl-1,4,7,10,13-pentaoxotridecyl)benzophenone, thioxanthone, 2-chlorothioxanthone, 3-methylthioxanthone, 2,4-dimethylthioxanthone, 2-methylanthraquinone, 2-ethylanthraquinone, 2-t-butylanthraquinone, 2-aminoanthraquinone, and derivatives thereof.

The content of the photopolymerization initiator is preferably 0.01 to 5 parts by mass, more preferably not less than 0.03 parts by mass and not greater than 4 parts by mass, and particularly preferably not less than 0.05 parts by mass and not greater than 3 parts by mass with respect to 100 parts by mass of the (meth)acrylic acid ester copolymer. With the photopolymerization initiator in such a range, a favorable crosslinking reaction proceeds.

### <Other Components>

The present adhesive composition can contain other components, in addition to the (meth)acrylic acid ester copolymer, the crosslinker, and the photopolymerization initiator.

The “other components” are not limited. Examples include an antirust agent and a silane coupling agent, which will be described below.

The antirust agent is preferably triazoles and benzotriazoles, for example. The antirust agent can prevent corrosion of a transparent electrode on a touch panel.

The antirust agent is contained preferably in the amount of 0.01 to 5% by mass, more preferably in the amount of not less than 0.1% by mass and not greater than 3% by mass in the present adhesive composition (100% by mass).

Examples of the silane coupling agent can include silane coupling agents containing a glycidyl group and silane coupling agents having a (meth)acryl group or a vinyl group.

Containing these silane coupling agents can improve the adhesiveness to a member sheet or a flexible member when a laminate is formed using the adhesive sheet, and can suppress a foaming phenomenon under a moist and hot environment.

The silane coupling agent is contained preferably in the amount of 0.01 to 3% by mass, more preferably in the amount of not less than 0.1% by mass and not greater than 1% by mass in the present adhesive composition (100% by mass).

Even the content of the silane coupling agent of 0.01% by mass can bring about the effects for some adherends, while adjusting to not greater than 3% by mass can suppress foaming due to dealcoholization.

The present adhesive composition may contain, as other components, one or a combination of two or more of additives including curing accelerator, filler, coupling agent, UV absorber, UV stabilizer, antioxidant, stabilizer, and pigment.

Typically, it is preferable that the amount of these additives is selected so as not to adversely affect curing of the adhesive sheet and not to adversely affect the physical properties of the adhesive sheet.

### <Constitution of Present Adhesive Sheet>

The present adhesive sheet may be a single-layer sheet of only an adhesive layer formed from the present adhesive composition (also referred to as “the present adhesive layer”) or may be a multilayer sheet including the present adhesive layer and other layers.

When the present adhesive sheet is a multilayer sheet including other layers, it is preferable that the present adhesive layer has a largest thickness among the layers that constitute the present adhesive sheet.

In terms of enjoying the effects of the present disclosure, the thickness of the present adhesive layer preferably accounts for 10 to 90% of the total thickness of the present adhesive sheet, more preferably accounts for not less than 20% and not greater than 80%, and even more preferably not less than 30% and not greater than 70%.

### <Physical Properties of Present Adhesive Sheet>

The present adhesive sheet can have the following physical properties.

### (Storage Shear Modulus)

In the present adhesive sheet, the storage shear modulus at −30° C. (G′ (−30° C.)) obtained by dynamic viscoelasticity measurement with a shearing mode at a frequency of 1 Hz is not greater than 250 kPa, preferably not greater than 200 kPa, even more preferably not greater than 180 kPa, and particularly preferably not greater than 150 kPa.

The lower limit of the storage shear modulus (G′ (−30° C.)) of the present adhesive sheet is preferably not less than 10 kPa in view of shape retention.

With the storage shear modulus (G′ (−30° C.)) of the present adhesive sheet within the above range, the interlayer stress in folding a laminated sheet or a flexible image display device member can be reduced particularly from low temperature to high temperature, for example, when the present adhesive sheet is affixed to a member sheet to form a laminated sheet or a flexible image display device member. Accordingly, cracking of the member sheet or the flexible member can be suppressed.

### (Maximum Point of Loss Tangent (tan δ) and Glass Transition Temperature (Tg))

In the present adhesive sheet, the loss tangent (tan δ) obtained by dynamic viscoelasticity measurement with a shearing mode at a frequency of 1 Hz preferably has a maximum point at preferably not greater than −40° C. The maximum point of the loss tangent (tan δ) can be interpreted as a glass transition temperature (Tg). When the glass transition temperature (Tg) is within the above range, the storage shear modulus (G′ (−30° C.)) of the present adhesive sheet can be easily adjusted to not greater than 250 kPa.

As used herein “glass transition temperature” is a temperature at which the peak of primary dispersion of the loss tangent (tan δ) appears. Therefore, when the loss tangent (tan δ) obtained by dynamic viscoelasticity measurement with a shearing mode at a frequency of 1 Hz has only one maximum point observed, in other words, when the tan δ curve exhibits a single-peak shape, the glass transition temperature (Tg) can be considered to be single.

The “maximum point” of the loss tangent (tan δ) means a peak value in the tan δ curve, namely, a point having the maximum value among inflection points where a differentiated value changes from positive (+) to negative (−) in a predetermined range or in an entire range.

The elastic moduli (storage shear moduli) G′, the viscosity (loss shear modulus) G″, and tan δ=G″/G′ at various temperatures can be measured by using a strain rheometer.

The storage shear modulus (G′), the loss shear modulus (G″), and the loss tangent (tan δ) can be adjusted to the above ranges by adjusting types, blending amounts, weight average molecular weights, and the like of the components of the adhesive composition (for example, the monomer components that constitute the (meth)acrylic acid ester copolymer, and the crosslinker) that constitute the present adhesive sheet, or further adjusting the gel fraction and the like of the adhesive sheet.

The adjusting method is not limited to these methods.

### (Strain Recoverability)

In the present adhesive sheet, the strain recovery rate (400%, 1 minute) calculated by the method described in Examples is not less than 70%, preferably not less than 75%, even more preferably not less than 80%, and particularly preferably not less than 82%.

The upper limit of the strain recovery rate (400%, 1 minute) of the present adhesive sheet is preferably not greater than 99% in view of being an adhesive.

With the strain recovery rate (400%, 1 minute) of the present adhesive sheet within the above range, the adhesive sheet has excellent recoverability without leaving the effect caused by being placed into a bent state even with folding operations performed at low temperature, when the present adhesive sheet is affixed to a member sheet to form a laminated sheet or a flexible image display device member.

The strain recovery rate (400%, 1 minute) can be adjusted to the above ranges by adjusting types, blending amounts, weight average molecular weights, and the like of the components of the adhesive composition (for example, the monomer components that constitute the (meth)acrylic acid ester copolymer, and the crosslinker) that constitute the present adhesive sheet, or further adjusting the gel fraction and the like of the adhesive sheet.

The adjusting method is not limited to these methods.

### (Gel Fraction)

In the present adhesive sheet, the gel fraction calculated by the method described in Examples is preferably not less than 45% by mass, further preferably not less than 50% by mass, and more preferably not less than 60% by mass. The present adhesive sheet having a gel fraction not less than the above lower limit can sufficiently retain the shape.

On the other hand, the gel fraction of the present adhesive sheet is preferably not greater than 90% by mass, further preferably not greater than 85% by mass, and more preferably not greater than 80% by mass.

The present adhesive sheet having a gel fraction not greater than the above upper limit can be increased in adhesive force.

### (Thickness)

The thickness of the present adhesive sheet is not limited. The thickness of not less than 5 μm yields good handleability, and the thickness of not greater than 1000 μm can contribute to thinning of the laminate. Thus, the thickness of the present adhesive sheet is preferably not less than 5 μm, more preferably not less than 8 μm, and particularly preferably not less than 10 μm.

On the other hand, the upper limit is preferably not greater than 1000 μm, more preferably not greater than 500 μm, and particularly preferably not greater than 250 μm.

### <Preferable Use of Present Adhesive Sheet>

The present adhesive sheet is preferably used for laminating a member that constitutes a display member (also referred to as “display member”), specifically a flexible member for a display used for producing the display. The present adhesive sheet is particularly preferably used as an adhesive part for a flexible display used for producing the flexible display.

The same flexible member as those described later can be used.

### <Method for Manufacturing Present Adhesive Sheet>

Next, a method for manufacturing the present adhesive sheet will be described.

The following description is an example of the method for manufacturing the present adhesive sheet, and the present adhesive sheet is not limited to those manufactured by the following manufacturing method.

The present adhesive sheet can be produced by preparing the present adhesive composition containing a (meth)acrylic acid ester copolymer (including a partially polymerized product obtained by polymerizing monomer components that constitute the copolymer) or a mixture of monomer components that constitute the copolymer, a crosslinker, a photopolymerization initiator, other components, and the like; forming the present adhesive composition into a sheet; polymerizing (which has a meaning that encompasses “crosslinking”; the same applies hereinafter) and curing the (meth)acrylic acid ester copolymer and/or the crosslinker; and, if necessary, performing appropriate processing. In this way, the present adhesive sheet has a polymerized product (which has a meaning that encompasses “crosslinked product”; the same applies hereinafter), that is, a cured product of the (meth)acrylic acid ester copolymer.

When the adhesive composition is prepared, the raw materials may be kneaded by using a temperature-controllable kneader (for example, a uniaxial extruder, a biaxial extruder, a planetary mixer, a biaxial mixer, and a pressurizing kneader).

When the raw materials are mixed, additives such as silane coupling agent and antioxidant may be blended with the resin in advance and then supplied into the kneader, or all the materials may be melt-mixed in advance and then supplied, or only the additives may be condensed into the resin in advance to produce a master batch and then supplied.

As the method for forming the present adhesive composition into a sheet, a known method can be employed, such as a wet-laminating method, a dry-laminating method, an extrusion casting method using a T-die, an extrusion laminating method, a calender method, an inflation method, an injection molding method, and a liquid-injecting curing method. Among these, a wet-laminating method, an extrusion casting method, and an extrusion laminating method are preferable for manufacturing the sheet.

In order to impart curability to the present adhesive sheet, a crosslinker and/or a polymerization initiator may be used to polymerize, in other words, crosslink the present adhesive composition as described above

When the present adhesive composition contains a photopolymerization initiator, the present adhesive composition can be polymerized and cured with heat and/or active energy radiation.

For example, the present adhesive sheet can be manufactured by irradiating a formed product of the present adhesive composition, for example a sheet, with heat and/or active energy radiation.

Examples of the active energy radiation include ionizing radiations such as α-ray, β-ray, γ-ray, neutron beam, and electron beam, ultraviolet ray, and visible ray. Among these, ultraviolet ray is preferred in view of suppressing damage to an optical device constituent member and controlling a reaction.

The irradiation energy, irradiation time, irradiation method, and the like of the active energy radiation are not limited as long as the photopolymerization initiator is activated to polymerize the (meth)acrylic acid ester copolymer and/or the crosslinker.

When a hydrogen abstraction-type photopolymerization initiator is used as the photopolymerization initiator, the (meth)acrylic acid ester copolymer also undergoes a hydrogen abstraction reaction and not only the crosslinker but also the (meth)acrylic acid ester copolymer is incorporated into the crosslinked structure, thereby forming a crosslinked structure with many crosslinking points.

Therefore, it is even more preferable to use a hydrogen abstraction-type photopolymerization initiator to manufacture the present adhesive sheet.

Another method for manufacturing the present adhesive sheet that is different from the above method is a method involving: preparing the present adhesive composition in the same way as described above; coating a given member having a release-treated surface, for example, a release film, with the prepared adhesive composition; and curing the adhesive composition to form an adhesive layer (which has a meaning that encompasses “adhesive sheet”). However, the method is not limited to these methods.

In coating with the present adhesive composition as described above, the present adhesive composition may be dissolved in an appropriate solvent, if necessary.

As the method of coating with the present adhesive composition, any method that is a common coating method can be employed. Examples of the method include roll coating, die coating, gravure coating, comma coating, and screen printing.

When such a coating method is used, the present adhesive sheet can be obtained by thermal curing in addition to the curing by active energy radiation described above. In the case of coating, the thickness of the present adhesive sheet can be adjusted by a coating thickness and a solid-content concentration of a coating liquid.

In view of preventing blocking and preventing foreign matter adhesion, a protective film with a laminated release layer can be provided on at least one surface of the present adhesive sheet.

Emboss processing or various protrusions-and-depressions (such as cone or pyramid shape, or hemispherical shape) processing may be performed if necessary. For the purpose of improving adhesiveness to each member sheet, the surface may be subjected to surface treatment such as corona treatment, plasma treatment, and primer treatment.

### <<Present Laminated Sheet>>

A laminated sheet according to an example of the embodiment of the present disclosure (which hereinafter may be referred to as “the present laminated sheet”) is a sheet having a member sheet on at least one surface of the present adhesive sheet.

The present laminated sheet is preferably a laminated sheet having a constitution, for example, in which a member sheet (which hereinafter may be referred to as “first member sheet”), the present adhesive sheet, and a member sheet different from the above (which hereinafter may be referred to as “second member sheet”) are laminated in this order.

The present laminated sheet can be produced by affixing the present adhesive sheet to the first member sheet and/or the second member sheet. However, the manufacturing method is not limited to such a method.

The first member sheet and the second member sheet may be the same or different from each other.

### <Member Sheet>

Examples of the member sheet (which encompasses “the first member sheet” and/or “the second member sheet”) that constitutes the present laminated sheet, that is, the member sheet to be affixed to the present adhesive sheet include: a resin sheet containing, as a main component, one or two or more resins selected from the group consisting of cycloolefin resin, triacetylcellulose resin, polymethyl methacrylate resin, epoxy resin, polyimide resin, and polyurethane resin; or glass such as thin-film glass. Here, the thin-film glass refers to glass having a thickness of the aforementioned member sheet.

The term “main component” refers to a component that accounts for the highest mass proportion among the resin components that constitute the member sheet. Specifically, the main component accounts for not less than 50% by mass, preferably not less than 55% by mass, further preferably not less than 60% by mass, in a member sheet or a resin composition forming the member sheet.

Although depending on the constitution of a flexible image display device and the position of the present adhesive sheet, examples of the first member sheet and the second member sheet include a cover lens, a polarizing plate, a retardation film, a barrier film, a touch-sensor film, and a light-emitting element.

In particular, the first member sheet preferably has a touch input function in consideration of the constitution of an image display. When the present laminated sheet has the aforementioned second member sheet, the second member sheet may also have a touch input function.

### <Thickness of Present Laminated Sheet>

The thickness of the present laminated sheet is not limited. For example, the present laminated sheet is, as an example, a sheet when used for an image display device. The thickness of the sheet of not less than 0.01 mm yields good handleability, and the thickness of not greater than 1 mm can contribute to thinning of the laminate. Therefore, the thickness of the present laminated sheet is preferably not less than 0.01 mm, further preferably not less than 0.03 mm, and particularly preferably not less than 0.05 mm.

On the other hand, the upper limit is preferably not greater than 1 mm, further preferably not greater than 0.7 mm, and particularly preferably not greater than 0.5 mm.

The present adhesive sheet can be provided as an adhesive sheet with a release film by laminating a release film onto one surface or both surfaces of the adhesive layer composed of the present adhesive composition.

### <Method for Manufacturing Present Laminated Sheet>

Next, a method for manufacturing the present laminated sheet will be described.

The following description is an example of the method for manufacturing the present laminated sheet, and the present laminated sheet is not limited to those manufactured by the following manufacturing method.

The present laminated sheet may be manufactured by preparing the present adhesive composition in the same way as in the method for manufacturing the present adhesive sheet, and applying and curing the present adhesive composition, for example, on the first member sheet and/or the second member sheet.

In this case, the method for preparing the present adhesive composition, the coating method, the method for curing the present adhesive composition, and the like are the same as those in the method for manufacturing the present adhesive sheet.

Alternatively, the present laminated sheet may be manufactured by laminating the present adhesive sheet manufactured in advance with the first member sheet and/or the second member sheet.

For the purpose of improving adhesiveness, each of surfaces of the present adhesive sheet, the first member sheet, and the second member sheet may be subjected to surface treatment such as corona treatment, plasma treatment, and primer treatment.

When the present laminated sheet has a constitution in which the member sheet is laminated to only one surface of the present adhesive sheet, a protective film with a laminated release layer can be provided on the other surface of the present adhesive sheet that is not laminated with the member sheet.

### <Present Flexible Image Display Device Member>

A flexible image display device member according to an example of the embodiment of the present disclosure (which hereinafter may be referred to as “the present flexible image display device member”) is a flexible image display device member having a constitution in which two flexible members are laminated with the present adhesive sheet interposed therebetween.

Among constituent elements in the present flexible image display device member, the present adhesive sheet is the same as above. Elements other than the adhesive sheet will be described hereinafter.

### (Flexible Member)

Examples of the flexible member that constitutes the present flexible image display device member include: flexible displays, such as an organic electroluminescence (EL) display; and flexible members for a display, such as a cover lens (cover film), a polarizing plate, a polarizer, a retardation film, a barrier film, a viewing-angle compensating film, a luminescence improving film, a contrast improving film, a diffusing film, a semitransparent reflective film, an electrode film, a transparent conductive film, a metal mesh film, and a touch sensor film. Two of any one or two of them may be used in combination. Examples of the combination include: a combination of a flexible display and another flexible member; and a combination of a cover lens and another flexible member.

The flexible member means a bendable member, specifically a repeatedly bendable member. The flexible member is preferably a member fixable in a curved shape with a bending radius of not less than 25 mm, particularly a member that can withstand repeated bending actions with a bending radius of less than 25 mm, more preferably a bending radius of less than 3 mm.

In the above constitution, examples of the main component of the flexible member include cycloolefin resin, triacetylcellulose resin, polymethyl methacrylate resin, polyurethane, epoxy resin, polyimide resin, and glass. The main component may be one resin or two or more resins of these resins.

As used herein “the main component” refers to a component that accounts for the highest mass proportion among components that constitute the flexible member. Specifically, the main component accounts for preferably not less than 50% by mass, further preferably not less than 55% by mass, particularly preferably not less than 60% by mass, in a resin composition forming the flexible member. The flexible member may be composed of thin-film glass.

### <Method for Manufacturing Present Flexible Image Display Device Member>

A method for manufacturing the present flexible image display device member is not limited. The present adhesive composition may be applied on a flexible member, or the present adhesive composition may be formed into a sheet in advance and then the sheet may be laminated with a flexible member.

### <Present Image Display Device>

An image display device according to an example of the embodiment of the present disclosure (which hereinafter may be referred to as “the present image display device”) is an image display device in which the present laminated sheet or the present flexible image display device member is integrated. For example, a flexible image display device having the present laminated sheet can be formed by laminating the present laminated sheet to another image display device constituent member.

The term “flexible image display device” refers to an image display device that leaves no folding trace even when repeatedly folded, that can quickly recover to a state before folding when unfolded, and that can display a strain-free image even when folded.

More specific examples include an image display device composed of a member fixable in a curved shape with a bending radius of not less than 25 mm, particularly, a member that can withstand repeated bending actions with a bending radius of less than 25 mm, more preferably a bending radius of less than 3 mm.

One of features of the present laminated sheet is that an image display device having excellent flexibility can be produced, because delamination and cracking of the laminated sheet can be prevented even with folding operations under a low temperature environment, and the recoverability is good.

### EXAMPLES

The present disclosure will be described in detail below with Examples. However, the present disclosure is not limited to the following Examples as long as it does not depart from the spirit thereof. In Examples, “parts” and “%” means those on a mass basis.

First, an adhesive composition containing a (meth)acrylic acid ester copolymer, a crosslinker, and the like used in Examples and Comparative Examples will be described in detail below.

### (1) (Meth)Acrylic Acid Ester Copolymers (I to IV)

Table 1 lists compositions (mass proportions of monomer components) of (meth)acrylic acid ester copolymers (I to IV) used in Examples and Comparative Examples.

TABLE 1

| Composition of (meth)acrylic acid ester copolymer | | | | | |
|---|---|---|---|---|---|
| (parts by mass) | | I | II | III | IV |
| Monomer (A) | n-Octyl acrylate (NOAA) | 69.3 | 69.1 | 69.1 | — |
| component | Ethyl acrylate (EA) | 10 | 8.1 | 6.2 | — |
| | 2-Ethyhexyl acrylate (2EHA) | — | — | — | 75 |
| Monomer (B) | Methoxypolyethylene glycol methacrylate (n = 9) | 1.9 | 1.9 | 1.9 | — |
| component | Methoxypolyethylene glycol acrylate (n = 9) | 1.9 | 1.9 | 1.9 | — |
| Monomer (C) | Dimethylacrylamide (DMAA) | 1.9 | 1.9 | 1.9 | — |
| component | | | | | |
| Monomer (D) | 2-Hydroxyethyl acrylate (HEA) | 15 | 15.1 | 15.1 | 25 |
| component | 2-Acryloyloxyethylsuccinic acid | — | 1.9 | 1.9 | — |
| | 2-Methacryloyloxyethylsuccinic acid | — | — | 1.9 | — |

### (2) Crosslinker

A propylene glycol skeleton-containing monofunctional urethane acrylate (weight average molecular weight (Mw): about 10000, “PEM-X264” available from AGC Inc.), which is a photo-crosslinker, was used as the crosslinker.

### (3) Photopolymerization Initiator

A mixture of 4-methylbenzophenone and 2,4,6-trimethylbenzophenone (Esacure TZT available from IGM Resins), which is a hydrogen abstraction-type photopolymerization initiator, was used as the photopolymerization initiator.

### (4) Silane Coupling Agent

3-glycidoxypropyltrimethoxysilane was used as the silane coupling agent.

### (5) Ethyl Acetate

Ethyl acetate was used as a solvent.

### (6) Production of Adhesive Composition

The (meth)acrylic acid ester copolymers (I to IV) listed in Table 1 were blended with the aforementioned crosslinker, photopolymerization initiator, and silane coupling agent as specified in Table 2, and ethyl acetate was added so that the solid content concentration was 35%, yielding adhesive compositions of Examples and Comparative Examples.

TABLE 2

| | | | | | | | Comp. | Comp. | Comp. | Comp. |
|---|---|---|---|---|---|---|---|---|---|---|
| | | | Ex. 1 | Ex. 2 | Ex. 3 | Ex. 4 | Ex. 1 | Ex. 2 | Ex. 3 | Ex. 4 |
| (Meth)acrylic acid | I | Parts | 100 | — | — | — | 100 | — | — | — |
| ester copolymer | II | Parts | — | 100 | 100 | — | — | 100 | — | — |
| | III | Parts | — | — | — | 100 | — | — | 100 | — |
| | IV | Parts | — | — | — | — | — | — | — | 100 |

| | | | | | | | | | |
|---|---|---|---|---|---|---|---|---|---|
| Crosslinker | Parts | 52 | 50 | 75 | 50 | — | — | — | — |
| Photopolymerization initiator | Parts | 3 | 3 | 3 | 3 | 3 | 3 | 3 | 3 |
| Silane coupling agent | Parts | 0.4 | 0.4 | 0.4 | 0.4 | 0.2 | 0.2 | 0.3 | 0.4 |

| | | | | | | | | |
|---|---|---|---|---|---|---|---|---|
| UV dose (J/cm²) | 0.5 | 0.5 | 0.5 | 0.5 | 1 | 1 | 1 | 1 |

### <Production of Adhesive Sheet>

In Examples 1 to 4 and Comparative Examples 1 to 4, adhesive sheets were obtained as follows.

An adhesive composition was prepared by blending the raw materials in the mass proportions listed in Table 2 and mixing the raw materials homogeneously. Subsequently, the adhesive composition was applied to a 100 μm thick release film (PET film available from Mitsubishi Chemical Corporation) subjected to silicon release treatment by using an applicator to a thickness of 50 μm after drying of the solvent. After application, the coating was placed in a dryer heated to a temperature of 90° C. and retained for 10 minutes to evaporate the solvent contained in the adhesive composition.

Subsequently, on a surface of the solvent-dried adhesive composition, a 75 μm thick release film (PET film available from Mitsubishi Chemical Corporation) subjected to silicon release treatment was laminated, and the adhesive composition was irradiated with ultraviolet rays via the release film by using a high-pressure mercury so that the integrated quantity of light with a wavelength of 365 nm was the dose listed in Table 2, resulting in an adhesive sheet with release films in which release films were laminated on both front and back surfaces of the adhesive sheet.

### <Measurement/Evaluation of Adhesive Sheet>

Measurement and evaluation of the adhesive sheets obtained in Examples and Comparative Examples were performed as follows.

### <Dynamic Viscoelasticity>

The release films were removed from each of the adhesive sheets with release films produced in Examples and Comparative Examples, and a plurality of the adhesive sheets were laminated to form a laminate having a thickness of 0.8 mm. The obtained laminate was punched into a cylinder having a diameter of 10 mm (height of 1.0 mm) to form a measurement sample.

For the measurement sample, dynamic viscoelasticity measurement was performed by using a viscoelasticity measurement system (product name “DHR 20” available from T.A. Instruments) and parallel plates of 8 mm in diameter with a shearing mode at a frequency of 1 Hz and a strain of 0.1%, and the storage shear modulus (G′), the loss shear modulus (G″), loss tangent (tan δ) at each temperature were obtained.

### (Measurement Conditions)

Adhesion tool: 8 mm diameter parallel plates
Strain: 0.1%
Frequency: 1 Hz
Measurement temperature: −50 to 100° C.
Temperature rise rate: 5° C./min

### <Gel Fraction>

The release films were removed from each of the adhesive sheets with release films produced in Examples and Comparative Examples, and a plurality of the adhesive sheets were laminated to form a laminate having a thickness of 0.8 mm. The obtained laminate was used as a measurement sample.

The measurement sample was immersed in ethyl acetate for 24 hours and dried at 70° C. for 4.5 hours, and then the mass fraction of the residual gel component was determined as a gel fraction. The result was the average of measurement values of two samples.

### <Adhesive Force>

From each of the adhesive sheets with release films produced in Examples and Comparative Examples, one of release films was removed to expose the adhesive surface, to which a 50 μm thick polyester film (PET film available from Mitsubishi Chemical Corporation) subjected UV irradiation treatment by using a high-pressure mercury lamp so that the integrated quantity of light with a wavelength of 365 nm was 2 J/cm² was roll-laminated as a lining film by using a hand roller. The resulting laminate was cut into a 10 mm wide strip, and the adhesive surface exposed by removing the remaining release film was roll-laminated onto glass by using a hand roller. Subsequently, autoclave processing (60° C., gage pressure 0.2 MPa, for 20 minutes) was performed for finish-affixing to produce a sample composed of glass/adhesive sheet/polyester film for adhesive force measurement.

For the sample, the polyester film and the adhesive sheet were peeled from the glass at a temperature of 23° C. and a humidity of 50% RH, a peeling angle of 180°, and a peeling rate of 300 mm/min, and the peeling force (N/cm) at the interface between the glass and the adhesive sheet was measured. The result was the average of measurement values of three samples.

### <Strain Recoverability>

The release films were removed from each of the adhesive sheets with release films produced in Examples and Comparative Examples, and a plurality of the adhesive sheets were laminated to form a laminate having a thickness of 0.8 mm. The obtained laminate was punched into a cylinder having a diameter of 10 mm (height of 1.0 mm) to form a measurement sample.

The measurement sample was strained by 400% at a strain (%) according to the following formula at 25° C. and retained for 10 minutes, by using a dynamic viscoelasticity measurement system (product name “DHR 20” available from T.A. Instruments) and parallel plates of 8 mm in diameter.

$$Strain ( \% ) = radius ( r ) \times angle of torsion ( θ ) / thickness ( l ) \times 100$$

Thereafter, the strain application was removed and the recovery from the caused strain was measured. A strain recovery rate (400%, 1 minute) was calculated by using the following formula from a strain recovery value one minute after the removal of the strain application.

$$Strain recovery rate ( 400 \% , 1 minute ) = ( strain recovery value after one minute ( \% ) / 400 ( \% ) )$$

### <Low-Temperature Bending Durability>

The release films were removed from each of the adhesive sheets with release films produced in Examples and Comparative Examples, and a 23 μm thick cycloolefin polymer (COP) film and a 50 μm thick transparent polyimide film (CPI) were each roll-laminated by using a hand roller. Subsequently, autoclave processing (60° C., gage pressure 0.2 MPa, for 20 minutes) was performed for finish-affixing to produce a laminated sheet having three layers: COP/adhesive sheet/CPI. The obtained laminate was cut into a 40 mm wide strip and used as a measurement sample.

For the measurement sample, a folding test was performed with the COP side folded inward by using a folding environment tester (product name “ETS with CHAMBER CL09 type-D01” from Yuasa System Co., Ltd.) at a temperature of −20° C., bending R=2, bending rate 60 r/min, and the number of times of bending 100000.

The measurement sample after the folding test was evaluated as follows.

Good: no film cracking was found in the bending portion of the measurement sample after the folding test, and excellent bending durability at low temperature was confirmed.
Poor: film cracking occurred in the bending portion of the measurement sample after the folding test, and poor bending durability at low temperature was confirmed.

Table 3 lists the results obtained by the measurement and evaluation of the adhesive sheets.

TABLE 3

| | | | | | Comp. | Comp. | Comp. | Comp. |
|---|---|---|---|---|---|---|---|---|
| Measurement and evaluation result | Ex. 1 | Ex. 2 | Ex. 3 | Ex. 4 | Ex. 1 | Ex. 2 | Ex. 3 | Ex. 4 |
| G′ (−30° C.) [kPa] | 189 | 214 | 169 | 232 | 916 | 1057 | 1508 | 3900 |
| Maximum point (Tg) of tanδ [° C.] | −44 | −43 | −45 | −41 | −34 | −33 | −31 | −27 |
| Gel fraction (%) | 58 | 58 | 62 | 59 | 69 | 72 | 74 | 33 |
| Adhesion force (N/cm) | 2.4 | 2.4 | 1.8 | 2.4 | 3.6 | 3.4 | 2.8 | 14.9 |
| Strain recovery rate | 77 | 75 | 84 | 76 | 72 | 72 | 75 | 18 |
| (400%, 1 min) [%] | | | | | | | | |
| Low-temperature bending durability | Good | Good | Good | Good | Poor | Poor | Poor | Poor |

The adhesive sheets of Examples, each formed from an adhesive composition containing a (meth)acrylic acid ester copolymer of a specific composition and a crosslinker, achieved both of a low storage modulus at low temperature and strain recoverability, had excellent durability that suppresses cracking of a member sheet when repeatedly folded in a low temperature state and excellent recoverability that allows quick recovery to a flat state when a folding operation is performed, and were usable as adhesive sheets for flexible image display devices.

On the other hand, the adhesive sheets of Comparative Examples did not satisfy one of a low storage modulus at low temperature and strain recoverability or satisfied neither of them, and had member sheets cracked when repeatedly folded in a low temperature state. Thus, Comparative Examples were inferior as adhesive sheets for flexible image display devices.

The specific embodiments of the present disclosure have been demonstrated in the above Examples, but the above Examples are merely examples and should not be construed as limiting. Various modifications obvious to a person skilled in the art are intended to be included within the scope of the present disclosure.

### INDUSTRIAL APPLICABILITY

The present disclosure can provide an adhesive sheet for a flexible image display device that has excellent durability that prevents interlayer separation when folded in a low temperature state (which may be referred to as “low-temperature bending durability”) because of a low storage modulus at low temperature such as −30° C., and has excellent recoverability that allows quick recovery to a flat state when a folding operation is performed (also referred to as “strain recoverability”). Thus, the obtained adhesive sheet is useful as an adhesive sheet for various flexible image display devices such as bendable, foldable, rollable, and stretchable devices, and specifically suitable for an adhesive sheet for foldable image display devices that undergo repeated folding.

1. An adhesive sheet formed from an adhesive composition comprising a (meth)acrylic acid ester copolymer and a crosslinker, wherein
the (meth)acrylic acid ester copolymer comprises, as components that constitute the copolymer, (A) a branched or linear C1 to C20 alkyl (meth)acrylic acid ester monomer, (B) a monomer having an alkylene glycol group in a molecule and having a (meth)acryloyl group, and (C) a nitrogen-containing vinyl monomer, and
the adhesive sheet has a storage shear modulus at −30° C. (G′ (−30° C.)) of not greater than 250 kPa obtained by dynamic viscoelasticity measurement with a shearing mode at a frequency of 1 Hz, and has a strain recovery rate (400%, 1 minute) of not less than 70%.

2. The adhesive sheet according to claim 1, wherein the monomer component (A) is a linear C8 to C12 alkyl (meth)acrylic acid ester monomer.

3. The adhesive sheet according to claim 1, wherein the (meth)acrylic acid ester copolymer further comprises (D) a hydroxyl group-containing monomer and/or a carboxy group-containing monomer.

4. The adhesive sheet according to claim 1, wherein the adhesive composition comprises 20 to 90 parts by mass of the crosslinker with respect to 100 parts by mass of the (meth)acrylic acid ester copolymer.

5. The adhesive sheet according to claim 1, wherein the adhesive composition comprises 30 to 90 parts by mass of the crosslinker with respect to 100 parts by mass of the (meth)acrylic acid ester copolymer.

6. The adhesive sheet according to claim 1, wherein the crosslinker comprises a (meth)acrylate having an average functionality of not less than 1.0 and less than 2.0.

7. The adhesive sheet according to claim 1, wherein the crosslinker comprises a monofunctional urethane (meth)acrylate.

8. The adhesive sheet according to claim 1, wherein the monomer component (B) is alkoxypolyalkylene glycol (meth)acrylate.

9. The adhesive sheet according to claim 8, wherein the alkoxypolyalkylene glycol (meth)acrylate is contained in an amount of 2 to 4% by mass in an entirety of monomer components that constitute the (meth)acrylic acid ester copolymer.

10. The adhesive sheet according to claim 1, wherein the adhesive composition comprises a photopolymerization initiator.

11. A flexible image display device member comprising a constitution in which two flexible members are laminated with the adhesive sheet according to claim 1 interposed.

12. A flexible image display device comprising the flexible image display device member according to claim 11.
